(19) United States
(12) Patent Application Publication
(10) Pub. No.: US 2025/0174510 A1
(43) Pub. Date: May 29, 2025

(54) STRUCTURE AND FORMATION METHOD OF PACKAGE WITH HEAT DISSIPATION STRUCTURE

(71) Applicant: Taiwan Semiconductor Manufacturing Company, Ltd., Hsinchu (TW)

(72) Inventors: Ping-Yin HSIEH, Hsinchu City (TW); Yi Wen HUANG, Hsinchu City (TW); Yi-Huan LIAO, Hsinchu County (TW); Chih-Hao CHEN, Taipei city (TW); Li-Hui CHENG, New Taipei City (TW)

(21) Appl. No.: 18/522,583

(22) Filed: Nov. 29, 2023

(51) Int. Cl. H01L 23/367; H01L 23/00; H01L 23/498; H01L 25/00; H01L 25/065

(52) U.S. Cl. CPC H01L 23/367; H01L 23/49816; H01L 23/49822; H01L 23/49838; H01L 24/16; H01L 24/32; H01L 24/73; H01L 25/0655; H01L 25/50; H01L 2224/16225; H01L 2224/32225; H01L 2224/73204; H01L 2924/19101

(57) ABSTRACT

A package structure and a formation method are provided. The method includes disposing a chip-containing structure over a substrate. The method also includes attaching a heat dissipation structure to the substrate through an adhesive structure. The heat dissipation structure, the substrate, and the adhesive structure together surround a first space containing the chip-containing structure. The adhesive structure has a through-hole connecting the first space to a second space outside of the first space.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A package structure not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1I are cross-sectional views of various stages of a process for forming a portion of a package structure, in accordance with some embodiments.

FIG. 2 is a cross-sectional view of an intermediate stage of a process for forming a portion of a package structure, in accordance with some embodiments.

FIGS. 3A-3B are top views of various stages of a process for forming a portion of a package structure, in accordance with some embodiments.

FIGS. 4A-4B are cross-sectional views of various stages of a process for forming a portion of a package structure, in accordance with some embodiments.

FIGS. 5A-5C are cross-sectional views of various stages of a process for forming a portion of a package structure, in accordance with some embodiments.

FIGS. 6A-6C are cross-sectional views of various stages of a process for forming a portion of a package structure, in accordance with some embodiments.

FIGS. 7A-7B are cross-sectional views of various stages of a process for forming a portion of a package structure, in accordance with some embodiments.

FIGS. 8A, 8B, 8C, and 8D are top views each showing an intermediate stage of a process for forming a portion of a package structure, in accordance with some embodiments, in accordance with some embodiments.

FIG. 9 is a cross-sectional view of an intermediate stage of a process for forming a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows the testing through probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

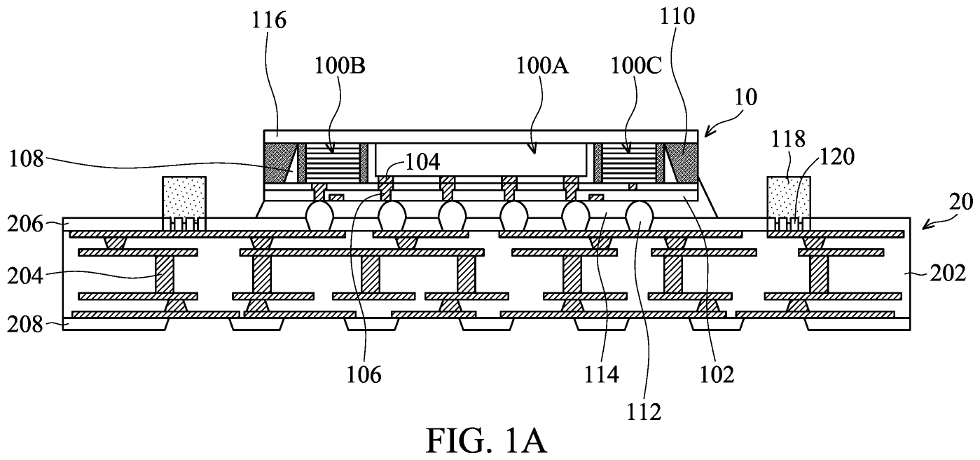

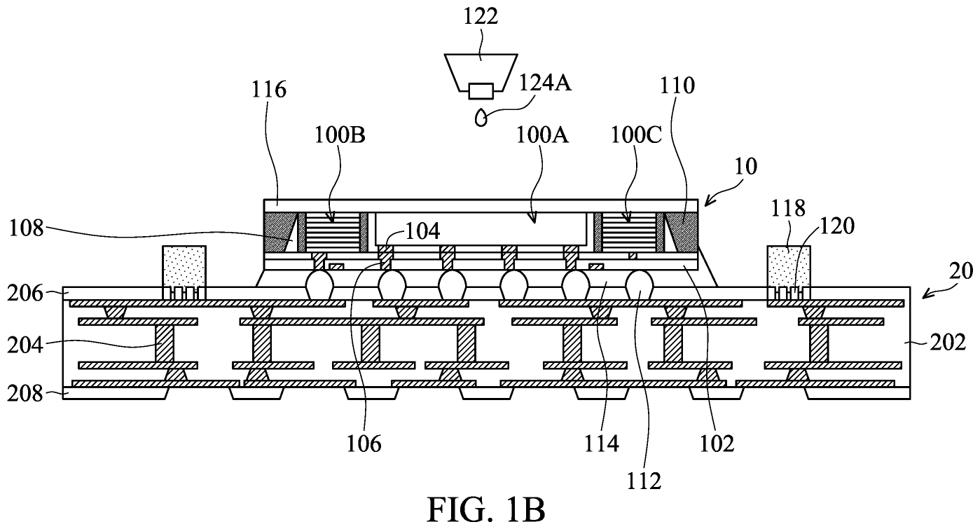

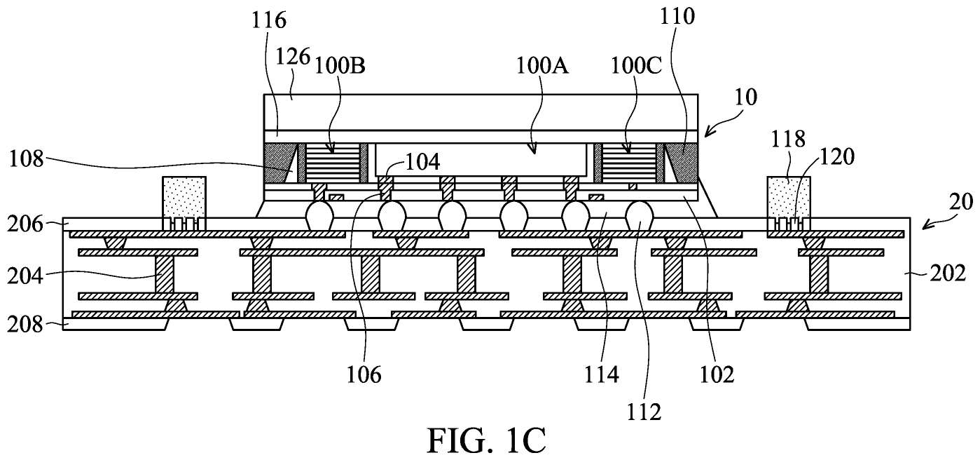

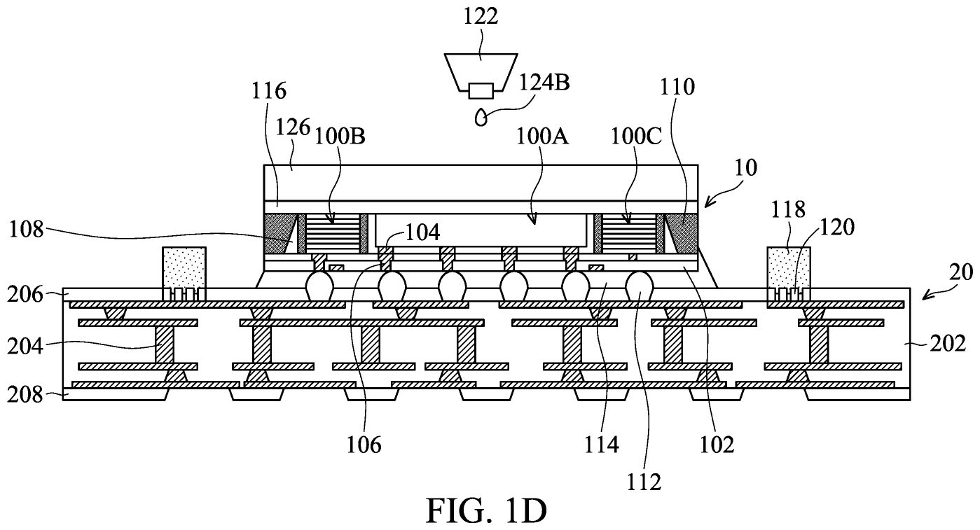

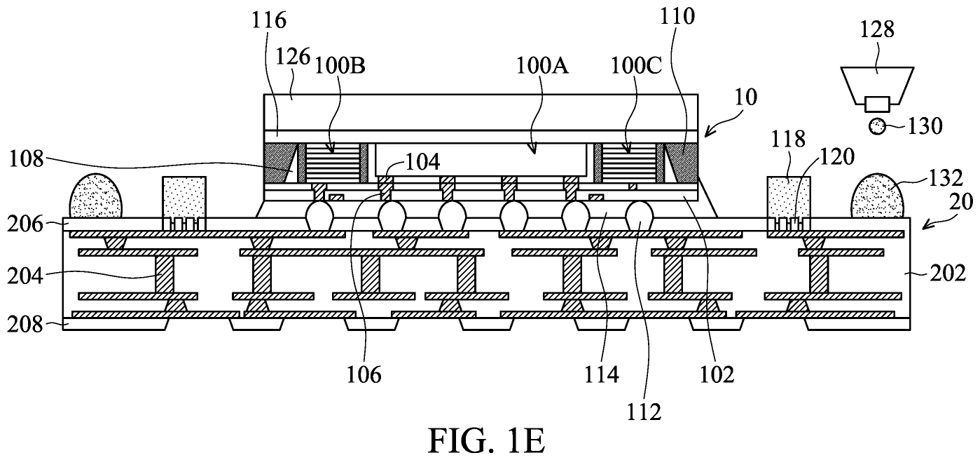

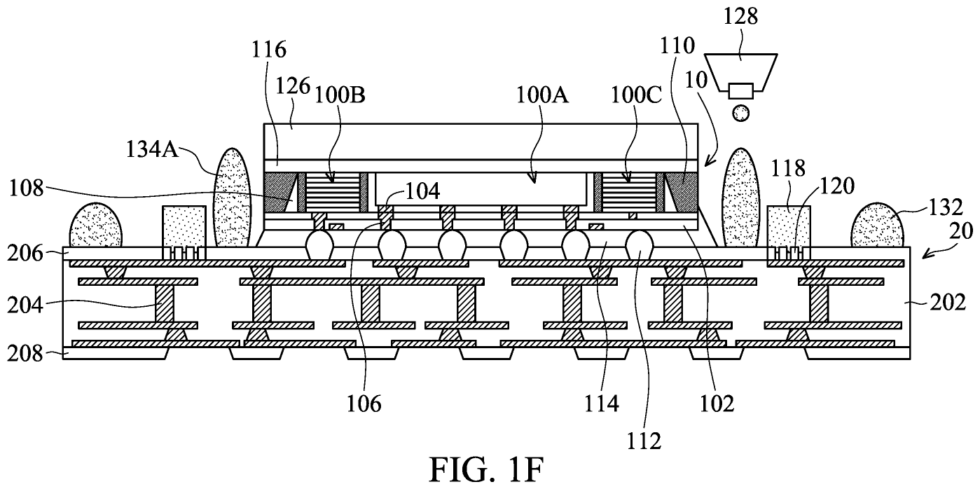

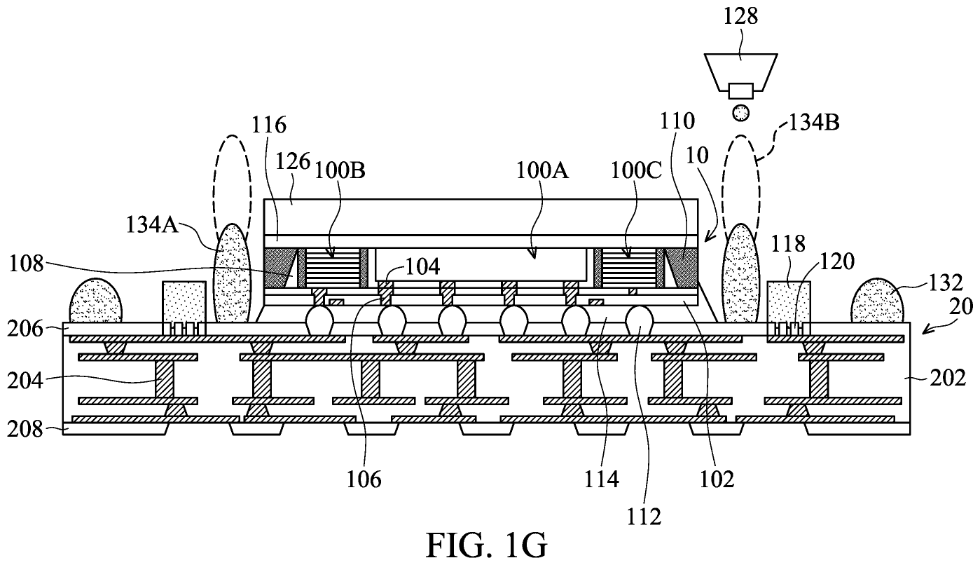

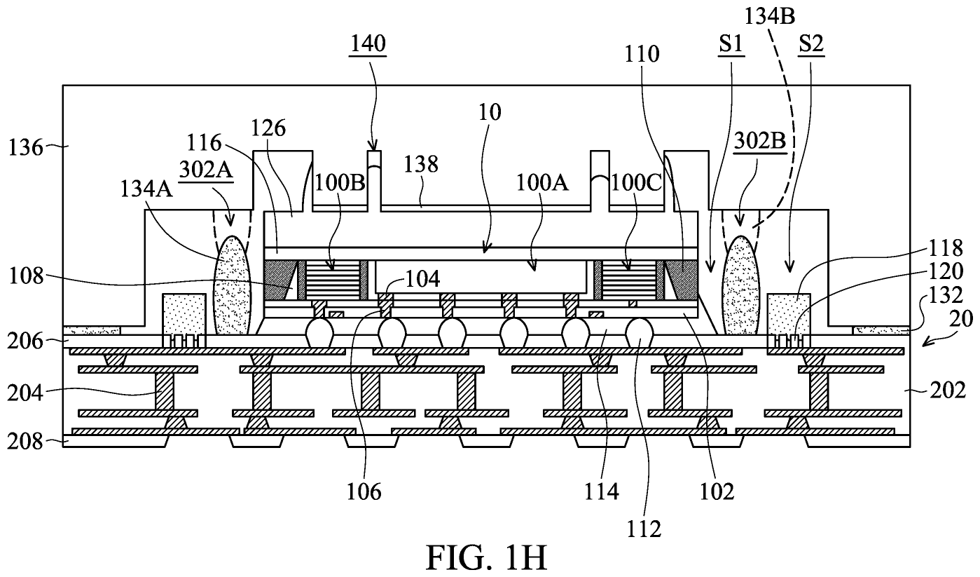

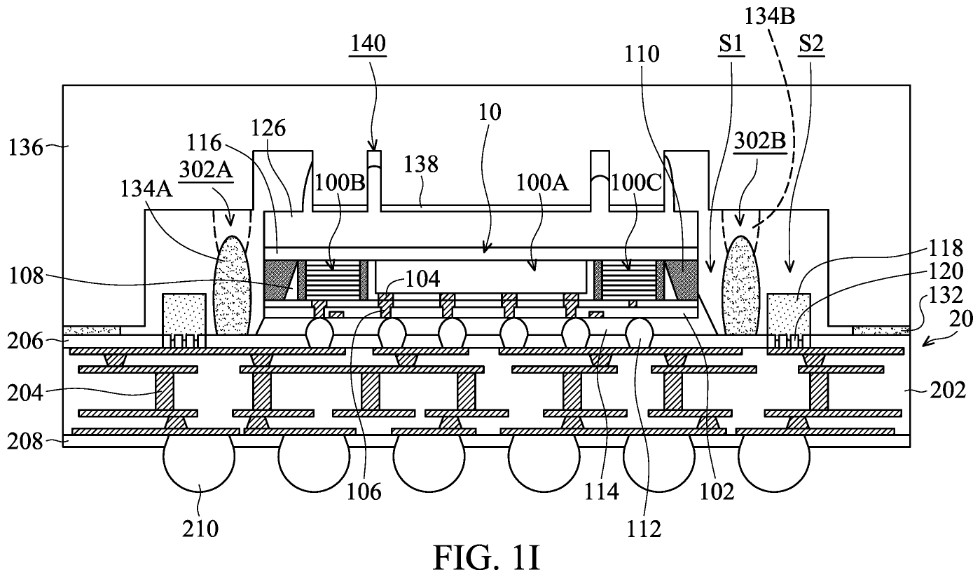

FIGS. 1A-1I are cross-sectional views of various stages of a process for forming a portion of a package structure, in accordance with some embodiments. As shown in FIG. 1A, a chip package 10 is disposed over a substrate 20, in accordance with some embodiments. In some embodiments, the chip package 10 is bonded to the substrate 20 through multiple bonding structures 112. The bonding structures 112 may be made of or include solder material. The solder material may be a tin-containing material. The tin-containing material may further include copper, silver, gold, aluminum, lead, one or more other suitable materials, or a combination thereof. In some other embodiments, the solder material is lead-free.

In some embodiments, an underfill structure 114 is formed to laterally surround and protect the bonding structures 112, as shown in FIG. 1A. A portion of the underfill structure 114 is between the substrate 20 and the bottom of the chip package 10. A second portion of the underfill structure 114 may extend upwards along sidewalls of the chip package 10. The underfill structure 114 may be made of or include an epoxy-based resin with fillers dispersed therein. The fillers may include fibers (such as silica fibers and/or carbon-containing fibers), particles (such as silica particles and/or carbon-containing particles), or a combination thereof.

In some embodiments, an underfill liquid is dispensed onto the substrate 20 along a side of the chip package 10. The underfill liquid may be made of or include a polymer material, such as an epoxy-based resin with fillers dispersed therein. The fillers may include fibers (such as silica fibers and/or carbon-containing fibers), particles (such as silica particles and/or carbon-containing particles), or a combination thereof. The underfill liquid may be drawn into the space between the substrate 20 and the chip package 10, so as to surround the bonding structures 112 by the capillary force. Due to the capillary force, the underfill liquid may extend upwards along the sidewalls of the chip package 10. Afterwards, a thermal operation may be used to cure the underfill liquid. As a result, the underfill structure 114 is formed.

In some embodiments, the chip package 10 contains multiple chip structures (or chip-containing structures). As shown in FIG. 1A, the chip package 10 includes chip structures 100A, 100B, and 100C. Each of the chip structures 100A-100C may be a single semiconductor die and/or system-on-integrated-chips (SoIC). For the system-on-integrated-chips, multiple semiconductor dies are stacked and bonded together to form electrical connections between these semiconductor dies. In some embodiments, the semiconductor dies are system-on-chip (SoC) chips that include multiple functions. In some embodiments, one or more of the chip structures 100A-100C include high-frequency devices, optoelectronic devices, photonic devices, logic devices, memory devices, one or more other suitable devices, or a combination thereof. In some embodiments, the chip structures 100B and 100C include multiple memory devices. In some embodiments, each of the chip structures 100B and 100C is used as a high bandwidth memory (HBM).

In some embodiments, the chip package 10 includes an interposer substrate 102, as shown in FIG. 1A. In some embodiments, the chip structures 100A-100C are bonded to the interposer substrate 102 through multiple bonding structures 104. Each of the bonding structures 104 may include a conductive pillar (such as a copper pillar) and a tin-containing solder bump. An underfill structure 108 may be formed over the interposer substrate 102, so as to laterally surround and protect the bonding structures 104. The material and formation method of the underfill structure 108 may be the same as or similar to those of the underfill structure 114.

In some embodiments, a protective layer 110 is formed over the interposer substrate 102 to encapsulate and protect the underfill structure 108 and the chip structures 100A-100C. The protective layer 110 may be made of or include a molding material. The protective layer 110 may be made of or include an epoxy-based resin with fillers dispersed therein. The fillers may include insulating fibers, insulating particles, one or more other suitable elements, or a combination thereof. In some embodiments, the average size of the fillers in the protective layer 110 is larger than that of the fillers in the underfill structure 108 or 114. In some embodiments, the weight percentage of the fillers in the protective layer 110 is greater than that of the fillers in the underfill structure 108 or 114.

In some embodiments, the interposer substrate 102 is a semiconductor substrate (such as a silicon substrate) that includes multiple through substrate vias (TSVs) 106 formed therein. The through substrate vias 106 may provide electrical connections between the elements (such as the chip structures 100A-100C) above the interposer substrate 102 and the elements (such as the bonding structures 112) below the interposer substrate 102.

However, embodiments of the disclosure are not limited thereto. Many variations and/or modifications can be made to embodiments of the disclosure. In some other embodiments, the interposer substrate 102 includes a polymer-based substrate that includes multiple conductive features formed therein. In some other embodiments, the interposer substrate 102 includes a polymer-based substrate and an interconnection die embedded in or surrounded by the polymer-based substrate.

In some embodiments, a backside metallization layer 116 is formed over the surfaces of the protective layer 108 and the chip structures 100A-100C, as shown in FIG. 1A. The backside metallization layer 116 may help to improve the adhesion between a subsequently disposed thermal conductive element and the chip package 10. The backside metallization layer 116 may be made of or include gold, nickel, copper, palladium, another suitable material, or a combination thereof.

As shown in FIG. 1A, one or more surface-mounted devices 118 are disposed over the substrate 20, in accordance with some embodiments. In some embodiments, the surface-mounted devices 118 are bonded to the substrate 20 through bonding structures 120. Each of the surface-mounted devices 118 is laterally spaced apart from the chip package 10, as shown in FIG. 1A.

Each of the surface-mounted devices 118 may include one or more passive devices such as resistors, capacitors, insulators, another suitable device, or a combination thereof. In some other embodiments, the surface-mounted devices 118 include one or more active devices such as transistor devices, diode devices, another suitable device, or a combination thereof. In some other embodiments, one or more of the surface-mounted devices 118 include a combination of passive devices and active devices.

In some embodiments, the substrate 20 is a circuit board that includes multiple insulating layers 202 and multiple conductive features 204 surrounded by the insulating layers 202. The conductive features 204 may include conductive lines and conductive vias. The substrate 20 may further include protective layers 206 and 208. The protective layers 206 and 208 may have multiple openings that expose some of the conductive features 204. Some of the conductive features 204 exposed by the openings of the protective layer 206 may be electrically connected to the bonding structures 112 thereabove, as shown in FIG. 1A.

As shown in FIG. 1B, a flux material 124A is provided on the backside metallization layer 116, in accordance with some embodiments. The flux material 124A may assist in a subsequent disposing of the thermal conductive element. In some embodiments, a flux jetting operation is performed using a flux provider 122, so as to provide the flux material 124A on the backside metallization layer 116. The flux material 124A may include one or more rosin, one or more acids, one or more alkalis, one or more solvents, another suitable material, or a combination thereof.

As shown in FIG. 1C, a thermal conductive element 126 is disposed over the chip package 10, in accordance with some embodiments. In some embodiments, the thermal conductive element 126 is made of or include a metal material. In some embodiments, the thermal conductive element 126 is made of or include a metal material that has a low melting point and has a low stress. The thermal conductive element 126 may be an indium-based material, a gallium-based material, another suitable material, or a combination thereof.

However, embodiments of the disclosure are not limited thereto. Many variations and/or modifications can be made to embodiments of the disclosure. In some other embodiments, the thermal conductive element 126 is a thermal conductive glue. In some embodiments, the thermal conductive element 126 include a polymer material with fillers dispersed therein. The polymer material may include an epoxy-based glue and/or a silicone-based glue. The fillers may include silver fillers, silver-containing fillers, alumina fillers, alumina-containing fillers, copper fillers, copper-containing fillers, gold fillers, gold-containing fillers, graphene fillers, aluminum fillers, aluminum-containing fillers, graphene-containing fillers, one or more other suitable fillers, or a combination thereof. The fillers may be particles, fibers, or a combination thereof.

As shown in FIG. 1D, similar to the embodiments illustrated in FIG. 1B, a flux material 124B is provided on the thermal conductive element 126, in accordance with some embodiments. The flux material 124B may assist in a subsequent joint between the thermal conductive element 126 and a heat dissipation structure. In some embodiments, a flux jetting operation is performed using the flux provider 122, so as to provide the flux material 124B on the thermal conductive element 126.

As shown in FIG. 1E, one or more adhesive structures 132 are formed over the substrate 20, in accordance with some embodiments. In some embodiments, an adhesive provider 128 is used to dispense an adhesive material 130 over the substrate 20 at predetermined regions. The adhesive material 130 dispensed over the predetermined regions form the adhesive structures 132. The adhesive material 130 may be an epoxy-based glue, a silicone-based glue, another suitable glue, or a combination thereof. In some embodiments, the adhesive structures 132 laterally surround the surface-mounted devices 118 and the chip package 10.

As shown in FIG. 1F, an adhesive element 134A is formed over the substrate 20, in accordance with some embodiments. Similar to the embodiments illustrated in FIG. 1E, the adhesive provider 128 may be used to assist in the formation of the adhesive element 134A. In some embodiments, the adhesive element 134A laterally surrounds the chip package 10. In some embodiments, the adhesive element 134A is positioned between the chip package 10 and the surface-mounted device 118.

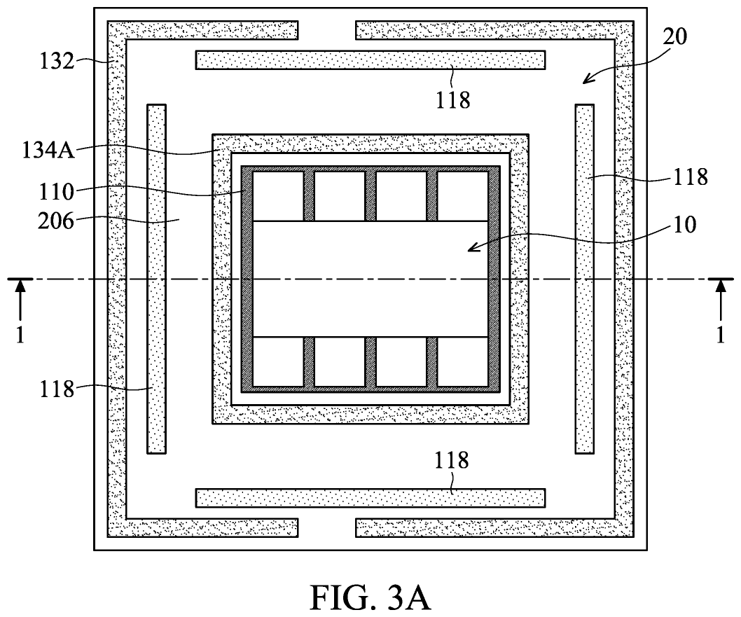

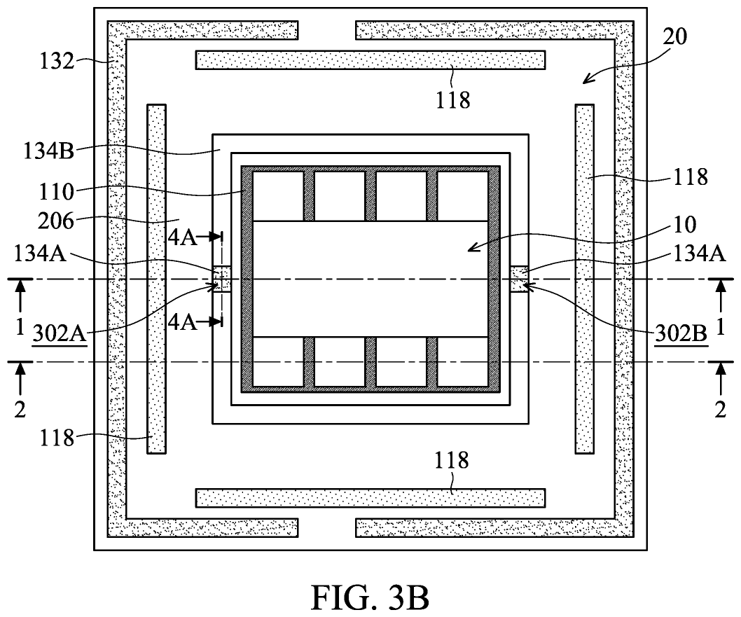

FIGS. 3A-3B are top views of various stages of a process for forming a portion of a package structure, in accordance with some embodiments. In some embodiments, FIG. 1F is a cross-sectional view of the package structure taken along the line 1-1 in FIG. 3A. In some embodiments, the adhesive element 134A is an adhesive ring that laterally and continuously surrounds the lower portion of the chip package 10, as shown in FIGS. 1F and 3A.

Afterwards, as shown in FIG. 3B, an adhesive element 134B is formed over the adhesive element 134A, in accordance with some embodiments. Similar to the embodiments illustrated in FIG. 1F, the adhesive provider 128 may be used to assist in the formation of the adhesive element 134B. As shown in FIG. 3B, the adhesive element 134B laterally surrounds the upper portion of the chip package 10. In some embodiments, the adhesive element 134B laterally surrounds the thermal conductive element 126 that is placed over the chip package 10. The adhesive elements 134A and 134B together form an adhesive structure that laterally surrounds the chip package 10.

In some embodiments, the adhesive element 134B has multiple through-holes (or openings) 302A and 302B that penetrate through the sidewalls of the adhesive element 134B, as shown in FIG. 3B. The through-holes 302A and 302B expose the adhesive element 134A underneath.

In some embodiments, FIG. 1G is the cross-sectional view of the package structure taken along the line 1-1 in FIG. 3B. Due to the through-holes 302A and 302B, the adhesive element 134B should not be seen in FIG. 1G. For clarification, in FIG. 1G, the profile of the nearby adhesive element 134B is shown in dashed lines.

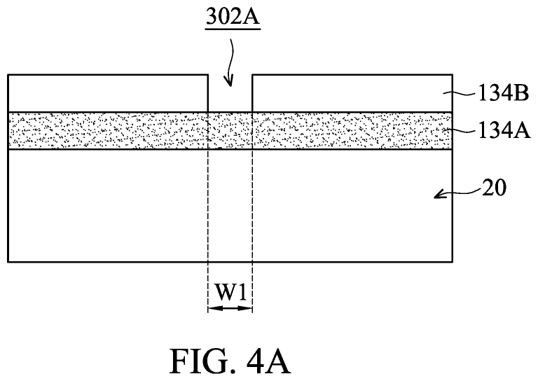

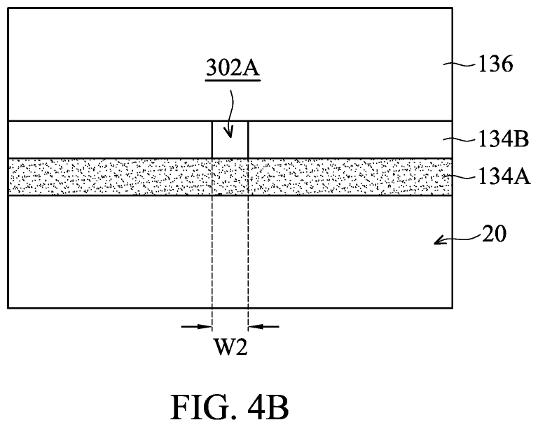

FIGS. 4A-4B are cross-sectional views of various stages of a process for forming a portion of a package structure, in accordance with some embodiments. In some embodiments, FIG. 4A is the cross-sectional view of the package structure taken along the line 4A-4A in FIG. 3B. As shown in FIG. 4A, the through-hole 302A has a width W1. In some embodiments, the width W1 is larger than about 0.5 mm to ensure that the through-hole 302A may be maintained open after the subsequent process that may involve a thermal compression process. For example, the width W1 may be within a range from about 0.5 mm to about 3 mm.

As shown in FIGS. 1H and 4B, a heat dissipation structure 136 is disposed over the chip package 10 and the substrate 20, in accordance with some embodiments. In some embodiments, the heat dissipation structure 136 is pressed against the thermal conductive element 126 and the adhesive element 134B at an elevated temperature. The elevated temperature may be within a range from about 130 degrees C. to about 200 degrees C. As shown in FIG. 1H, the adhesive structure 132 may help to adhere the heat dissipation structure 136 to the substrate 20.

As shown in FIG. 4B, after disposing the heat dissipation structure 136, the adhesive element 134B may be pressed to be thinner, in accordance with some embodiments. Due to the thermal compression process, the through-hole 302A may become narrower. As shown in FIG. 4B, the width of the through-hole 302A may be reduced to be the width W2.

In some embodiments, the heat dissipation structure 136 is a thermal conductive lid. The heat dissipation structure 136 may be made of or include copper, nickel, aluminum, gold, silver, steel, another suitable material, or a combination thereof. In some embodiments, the heat dissipation structure 136 has a main body that is made of or include copper. The heat dissipation structure 136 may further have one or more other layers coated on the main body. For example, these layers may include an inner layer made of nickel and one or more outer layers that are made of gold and/or silver.

In some embodiments, an interfacial layer 138 is formed on the surface of the heat dissipation structure 136 that faces the thermal conductive element 126. The interfacial layer 138 may be made of or include nickel, gold, another suitable material, or a combination thereof. In some embodiments, an intermetallic compound layer may be formed at the joint interface between the thermal conductive element 126 and the backside metallization layer 116 and/or between the thermal conductive element 126 and the interfacial layer 138. The intermetallic compound layer may be made of or include a compound material that contain Au—In, Ni—In, Ni—Au—In, another suitable material, or a combination thereof. The thickness of the intermetallic compound layer may be within a range from about 0.5 μm to about 2 μm.

In some embodiments, the heat dissipation structure 136 includes multiple trenches 140, as shown in FIG. 1H. In some embodiments, a portion of the thermal conductive element 126 extends into the trenches 140 after the heat dissipation structure 136 is disposed. The trenches 140 may help to keep the thermal conductive element 126 within the predetermined region. The thermal conductive element 126 may thus be prevented from reaching and negatively affecting other elements (such as the surface-mounted devices 118) nearby.

However, embodiments of the disclosure are not limited thereto. Many variations and/or modifications can be made to embodiments of the disclosure. In some other embodiments, the heat dissipation structures 136 does not include the trenches.

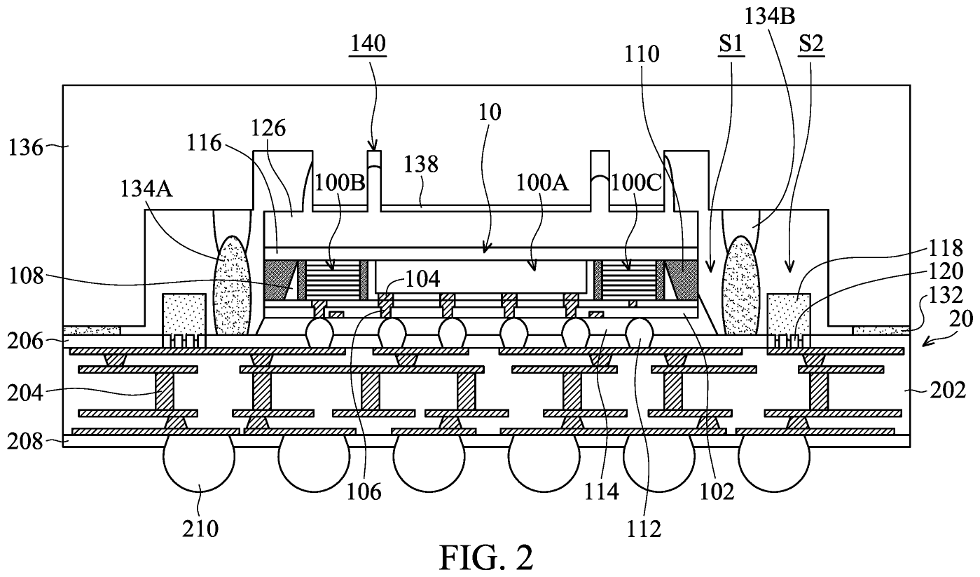

FIG. 2 is a cross-sectional view of an intermediate stage of a process for forming a portion of a package structure, in accordance with some embodiments. In some embodiments, FIG. 2 is the cross-sectional view of the package structure taken along the line 2-2 in FIG. 3B. As shown in FIGS. 1I and 2, the heat dissipation structure 136, the substrate 20, and the adhesive elements 134A and 134B together surround the space S1 that contains the chip package 10.

As shown in FIG. 1H, the through-holes 302A and 302B of the adhesive element 134B connects the space S1 to the space S2 that is outside of the space S1. During disposing the heat dissipation structure 136 or some subsequent reflow processes, one or more thermal processes may be performed. Due to the elevated temperature, the air in the space S1 may expanded. The expanded hot air is exhausted out of the space S1 through the through-holes 302A and 302B. The adhesive structure may be prevented from wall distortion due to the expansion of the hot air. The air pressure balance between the spaces S1 and S2 may thus be achieved. The adhesive structure that contains the adhesive elements 134A and 134B is prevented from deformation and distortion. The surface-mounted devices 118 that are nearby are prevented from being reached and/or negatively affected by the adhesive structure. The reliability and performance of the package structure are improved.

Afterwards, as shown in FIG. 1I, multiple bonding structures 210 are formed on the conductive features 204 that are exposed by the openings of the protective layer 208, in accordance with some embodiments. The bonding structures 210 may include tin-containing solder bumps.

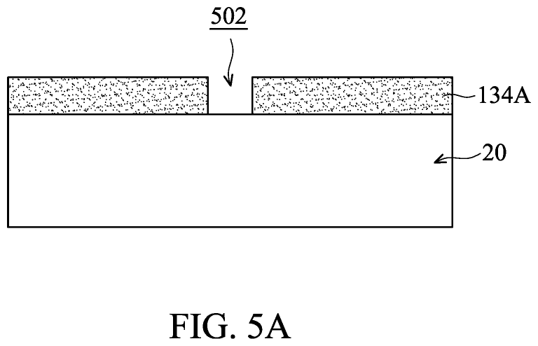

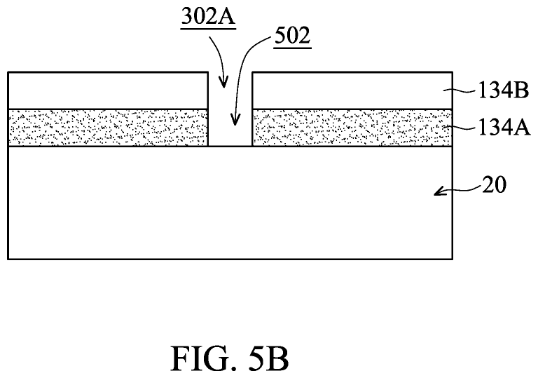

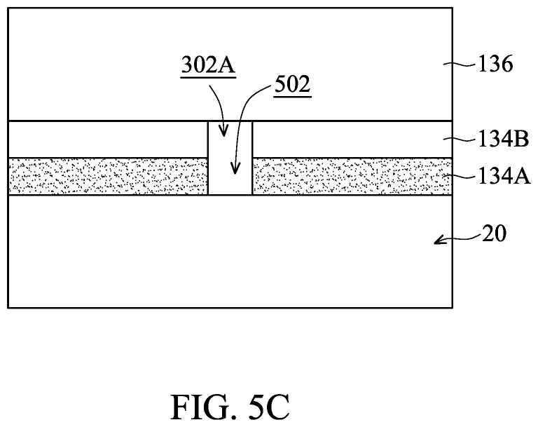

Many variations and/or modifications can be made to embodiments of the disclosure. FIGS. 5A-5C are cross-sectional views of various stages of a process for forming a portion of a package structure, in accordance with some embodiments. In some embodiments, the adhesive element 134A is not a continuous ring. A through-hole (or an opening) is formed in the adhesive element 134A. The profile of the through-hole 502 may be similar to that of the through-hole 134A shown in FIG. 3B.

As shown in FIG. 5B, the adhesive element 134B is then formed over the adhesive element 134A, in accordance with some embodiments. Similar to the embodiments shown in FIGS. 3B and 4A, the adhesive element 134B has a through-hole 302A. In some embodiments, the through-holes 302A and 502 are connected to each other.

As shown in FIG. 5C, similar to the embodiments illustrated in FIG. 4B, the heat dissipation structure 136 is pressed against the adhesive element 134B to adhere to the substrate 20, in accordance with some embodiments. The through-holes 302A and 502 may together provide a path for pressure release. The expanded hot air is allowed to be led out through the through-holes 302A and 502. The adhesive elements 134A and 134B may be prevented from deformation. The reliability and performance of the package structure are improved.

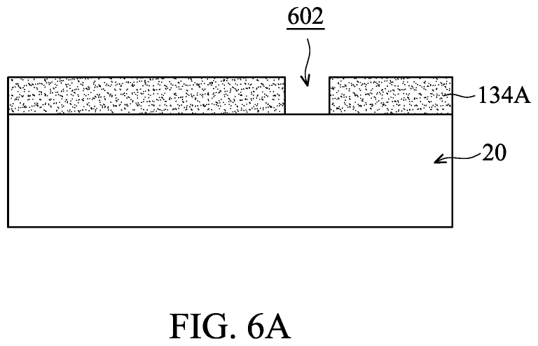

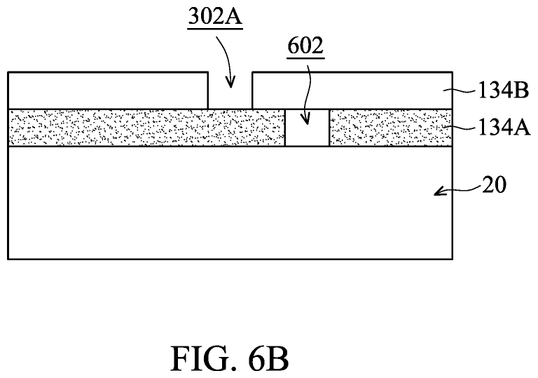

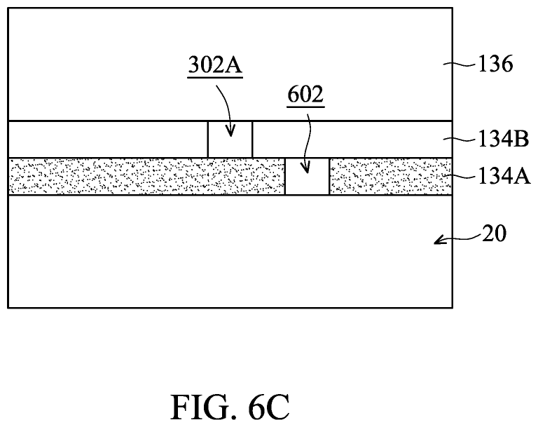

Many variations and/or modifications can be made to embodiments of the disclosure. FIGS. 6A-6C are cross-sectional views of various stages of a process for forming a portion of a package structure, in accordance with some embodiments. As shown in FIG. 6A, similar to the embodiments illustrated in FIG. 5A, a through-hole (or an opening) 602 is formed in the adhesive element 134A.

Afterwards, similar to the embodiments illustrated in FIG. 5B, the adhesive element 134B is then formed over the adhesive element 134A, as shown in FIG. 6B in accordance with some embodiments. Similar to the embodiments shown in FIGS. 3B and 4A, the adhesive element 134B has a through-hole 302A. In some embodiments, the through-holes 302A and 602 are misaligned with each other, as shown in FIG. 6B.

As shown in FIG. 6C, similar to the embodiments illustrated in FIG. 4B, the heat dissipation structure 136 is pressed against the adhesive element 134B to adhere to the substrate 20, in accordance with some embodiments. The through-holes 302A and 602 may provide paths for pressure release. The expanded hot air is exhausted out through the through-holes 302A and 602. The adhesive elements 134A and 134B may be prevented from deformation. The reliability and performance of the package structure are improved.

In some embodiments, the adhesive structure that contains the adhesive elements 134A and 134B are formed over the substrate 20 before the heat dissipation structure 136 is attached to the substrate 20. However, embodiments of the disclosure are not limited thereto. Many variations and/or modifications can be made to embodiments of the disclosure. In some other embodiments, the adhesive structure is formed on the heat dissipation structure 136 before the heat dissipation structure 136 is attached to the substrate 20.

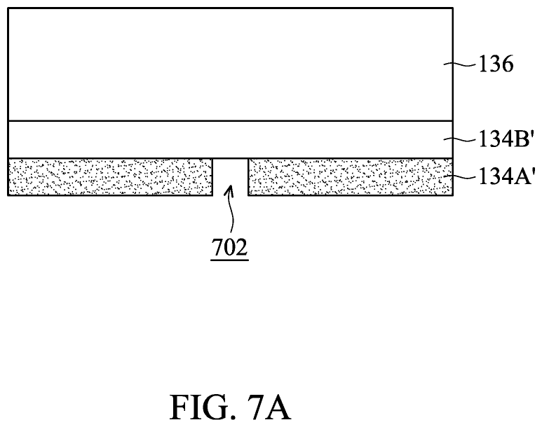

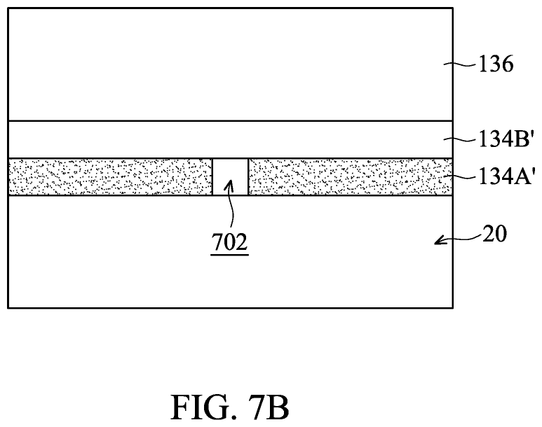

FIGS. 7A-7B are cross-sectional views of various stages of a process for forming a portion of a package structure, in accordance with some embodiments. As shown in FIG. 7A, adhesive elements 134B′ and 134A′ are formed over the heat dissipation structure 136. Similar to the through-hole 302A of the embodiments illustrated in FIG. 4A, the adhesive element 134A′ has a through-hole 702. The material and formation method of the adhesive elements 134B′ and 134A′ may be similar to those of the adhesive elements 134A and 134B.

As shown in FIG. 7B, the heat dissipation structure 136 is attached to the substrate 20, in accordance with some embodiments. The through-hole 702 may provide a path for pressure release. The expanded hot air is exhausted out through the through-hole 702. The adhesive elements 134A′ and 134B′ may thus be prevented from deformation. The reliability and performance of the package structure are improved.

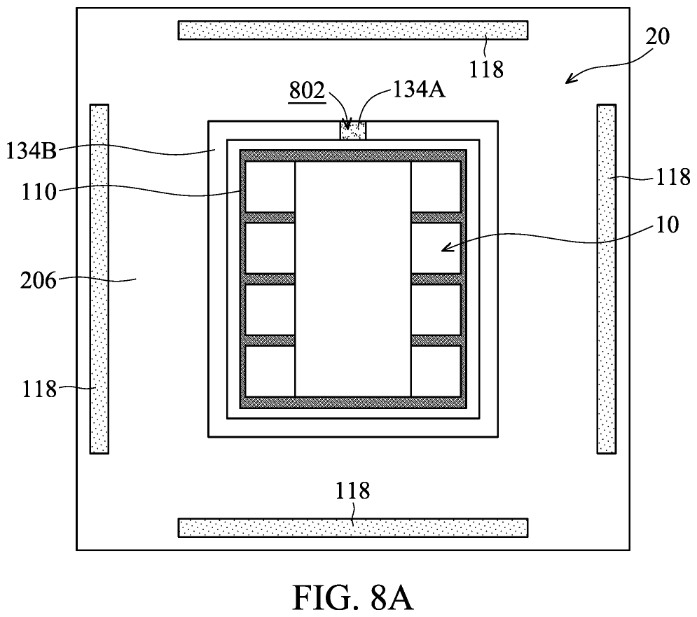

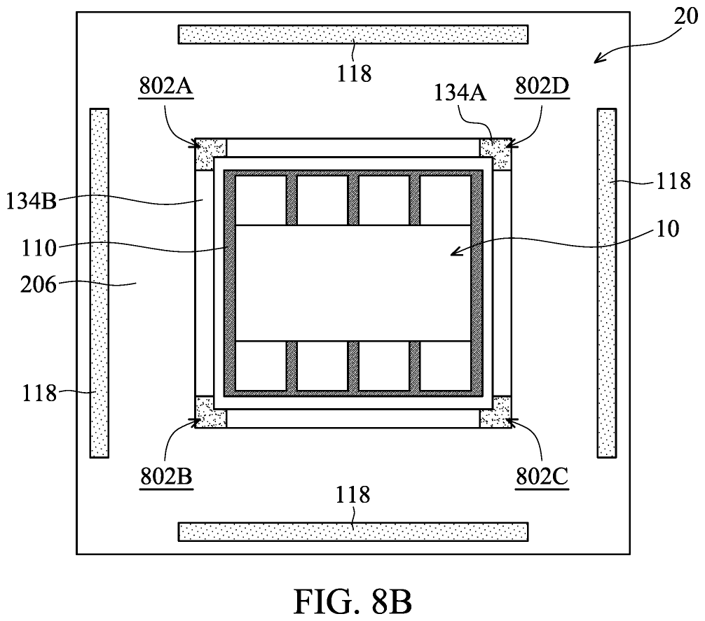

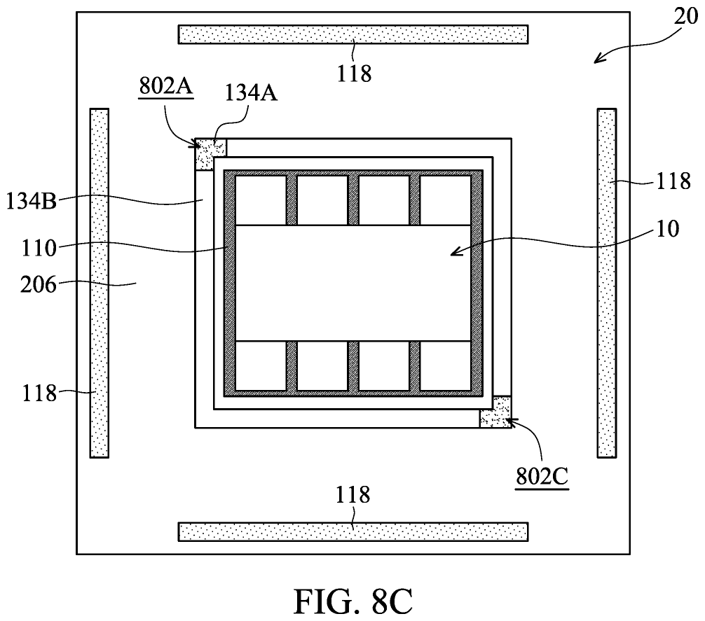

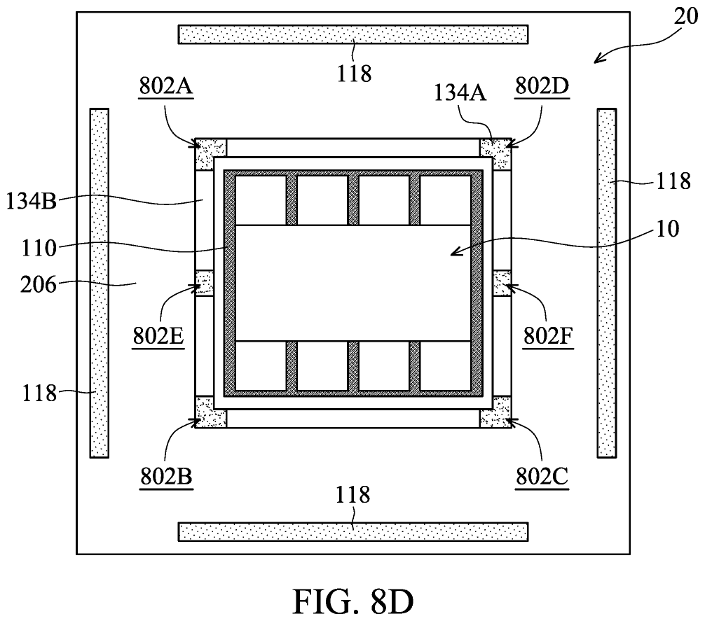

Many variations and/or modifications can be made to embodiments of the disclosure. FIGS. 8A, 8B, 8C, and 8D are top views each showing an intermediate stage of a process for forming a portion of a package structure, in accordance with some embodiments, in accordance with some embodiments.

As shown in FIG. 8A, there is only one through-hole 802 is formed in the adhesive element 134B, in accordance with some embodiments. The through-hole 802 allows the hot expanded air in the space surrounded by the adhesive elements 134A and 134B to be led out of the space. The high pressure in the space may thus be released. The adhesive elements 134A and 134B are thus prevented from being damaged. The reliability and performance of the package structure are improved.

In some embodiments, the through-holes penetrate the sidewalls of the adhesive structure that includes the adhesive elements 134A and 134B. However, embodiments of the disclosure are not limited thereto. Many variations and/or modifications can be made to embodiments of the disclosure. In some other embodiments, one or more through-holes are formed at the corner portions of the adhesive structure.

As shown in FIG. 8B, there are multiple through-holes 802A, 802B, 802C, and 802D formed in the adhesive element 134B, in accordance with some embodiments. Each of the through-holes 802A, 802B, 802C, and 802D exposes the adhesive element 134A underneath. In some embodiments, the through-holes 802A-802D penetrate through the corners of the adhesive element 134B, as shown in FIG. 8B. The through-holes 802A-802D allow the hot expanded air in the space surrounded by the adhesive elements 134A and 134B to be led out of the space. The high pressure in the space may thus be released. The adhesive elements 134A and 134B are thus prevented from being damaged. The reliability and performance of the package structure are improved.

Many variations and/or modifications can be made to embodiments of the disclosure. As shown in FIG. 8C, the through-holes 802A and 802C are formed at some corners of the adhesive structure, in accordance with some embodiments. The through-holes 802A and 802C allow the hot expanded air in the space surrounded by the adhesive elements 134A and 134B to be led out of the space. The high pressure in the space may thus be released. The adhesive elements 134A and 134B are thus prevented from being damaged. The reliability and performance of the package structure are improved.

Many variations and/or modifications can be made to embodiments of the disclosure. As shown in FIG. 8D, multiple through-holes 802A-802F are formed at different portions of the adhesive structure, in accordance with some embodiments. The through-holes 802A-802F allow the hot expanded air in the space surrounded by the adhesive elements 134A and 134B to be led out of the space. The high pressure in the space may thus be released. The adhesive elements 134A and 134B are thus prevented from being damaged. The reliability and performance of the package structure are improved.

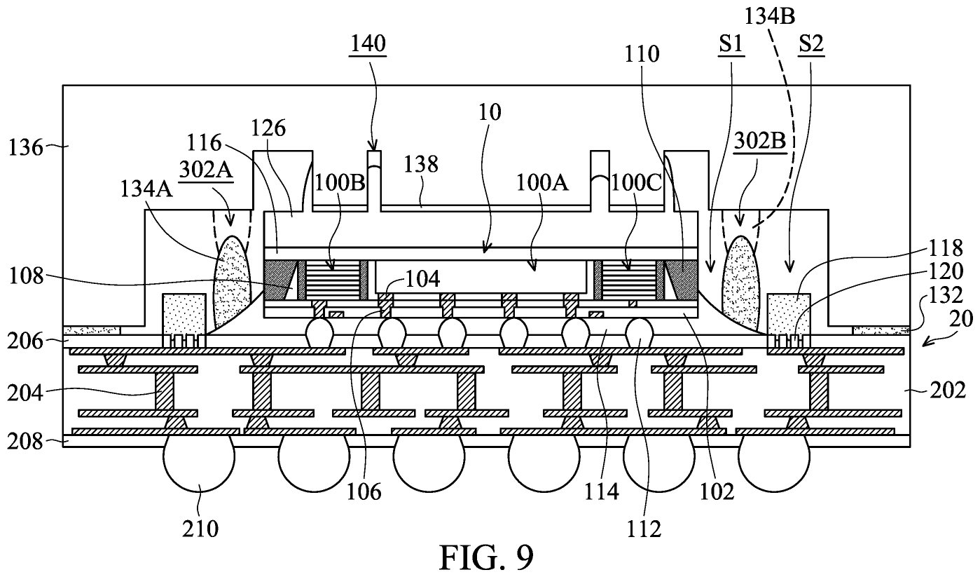

Many variations and/or modifications can be made to embodiments of the disclosure. FIG. 9 is a cross-sectional view of an intermediate stage of a process for forming a portion of a package structure, in accordance with some embodiments. In some embodiments, the adhesive element 134A is formed over the underfill structure 114. A portion of the underfill structure 114 is between the substrate 20 and the adhesive element 134A. In some embodiments, the adhesive element 134A is in direct contact with the underfill structure 114.

Embodiments of the disclosure form a package structure with a heat dissipation structure. A chip-containing structures is placed between the heat dissipation structure and a substrate. An adhesive structure that laterally surrounds the chip-containing structure is used to affix the heat dissipation to the substrate. The heat dissipation structure, the substrate, and the adhesive structure together surround the space that contains the chip-containing structure. One or more through-holes are formed in the adhesive structure. The through-holes connects the space that contains the chip-containing structure and a second space outside of the space. During the formation processes that may involve thermal operations, the expanded hot air in the space is exhausted out of the space. A pressure balance may thus be achieved. The adhesive structure may be prevented from wall distortion or deformation because of the expansion of the hot air. The reliability and performance of the package structure are significantly improved.

In accordance with some embodiments, a method for forming a package structure is provided. The method includes disposing a chip-containing structure over a substrate and disposing a thermal conductive element over the chip-containing structure. The method also includes forming a first adhesive element over the substrate, and the first adhesive element laterally surrounds the chip-containing structure. The method further includes forming a second adhesive element over the first adhesive element, and the second adhesive element laterally surrounds the thermal conductive element. In addition, the method includes disposing a heat dissipation structure over the chip-containing structure. The heat dissipation structure, the substrate, the first adhesive element, and the second adhesive element together surround a first space containing the chip-containing structure. One or two of the first adhesive element and the second adhesive element has a through-hole connecting the first space to a second space outside of the first space.

In accordance with some embodiments, a method for forming a package structure is provided. The method includes disposing a chip-containing structure over a substrate. The method also includes attaching a heat dissipation structure to the substrate through an adhesive structure. The heat dissipation structure, the substrate, and the adhesive structure together surround a first space containing the chip-containing structure. The adhesive structure has a through-hole connecting the first space to a second space outside of the first space.

In accordance with some embodiments, a package structure is provided. The package structure includes a substrate and a heat dissipation structure over the substrate. The package structure also includes a chip-containing structure between the substrate and the heat dissipation structure and an adhesive structure between the heat dissipation structure and the substrate. The heat dissipation structure, the substrate, and the adhesive structure together surround a first space containing the chip-containing structure. The package structure further includes a through-hole in the adhesive structure. The through-hole connects the first space to a second space outside of the first space.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
disposing a chip-containing structure over a substrate;
disposing a thermal conductive element over the chip-containing structure;
forming a first adhesive element over the substrate, wherein the first adhesive element laterally surrounds the chip-containing structure;
forming a second adhesive element over the first adhesive element, wherein the second adhesive element laterally surrounds the thermal conductive element; and
disposing a heat dissipation structure over the chip-containing structure, wherein the heat dissipation structure, the substrate, the first adhesive element, and the second adhesive element together surround a first space containing the chip-containing structure, and at least one of the first adhesive element and the second adhesive element has a through-hole connecting the first space to a second space outside of the first space.

2. The method for forming a package structure as claimed in claim 1, further comprising:
disposing a surface-mounted device over the package, wherein the first adhesive element is between the surface-mounted device and the chip-containing structure.

3. The method for forming a package structure as claimed in claim 2, further comprising:
forming a third adhesive element over the substrate, wherein the surface-mounted device is between the first adhesive element and the third adhesive element, and the third adhesive element adhere the heat dissipation structure to the substrate.

4. The method for forming a package structure as claimed in claim 1, wherein the first adhesive element is a continuous ring laterally surrounding a lower portion of the chip-containing structure, wherein the through-hole is in the second adhesive element.

5. The method for forming a package structure as claimed in claim 4, wherein the through-hole is in a sidewall of the second adhesive element.

6. The method for forming a package structure as claimed in claim 4, wherein the through-hole is in a corner of the second adhesive element.

7. The method for forming a package structure as claimed in claim 4, wherein the second adhesive element further has a second through-hole connecting the first space to the second space.

8. The method for forming a package structure as claimed in claim 1, wherein the disposing of the heat dissipation structure comprises pressing the heat dissipation structure against the second adhesive element and the thermal conductive element at an elevated temperature.

9. The method for forming a package structure as claimed in claim 1, wherein the heat dissipation structure has at least one trench, and a portion of the thermal conductive element extends into the at least one trench after the disposing of the heat dissipation structure.

10. The method for forming a package structure as claimed in claim 1, wherein the disposing of the chip-containing structure comprises bonding the chip-containing structure to the substrate through a plurality of solder bumps, and the method further comprises:
forming an underfill structure surrounding the solder bumps, wherein a portion of the underfill structure is between the substrate and the first adhesive element.

11. A method for forming a package structure, comprising:
disposing a chip-containing structure over a substrate; and
attaching a heat dissipation structure to the substrate through an adhesive structure, wherein the heat dissipation structure, the substrate, and the adhesive structure together surround a first space containing the chip-containing structure, and the adhesive structure has a through-hole connecting the first space to a second space outside of the first space.

12. The method for forming a package structure as claimed in claim 11, wherein the adhesive structure is formed over the substrate before the heat dissipation structure is attached to the substrate.

13. The method for forming a package structure as claimed in claim 11, wherein the adhesive structure is formed over the heat dissipation structure before the heat dissipation structure is attached to the substrate.

14. The method for forming a package structure as claimed in claim 11, wherein the formation of the adhesive structure comprises:
dispensing a first adhesive ring over the substrate, wherein the first adhesive ring laterally and continuously surrounds a lower portion of the chip-containing structure; and
dispensing a second adhesive element over the first adhesive ring, wherein the second adhesive element defines an opening partially exposing the first adhesive ring.

15. The method for forming a package structure as claimed in claim 11, further comprising:
bonding a surface-mounted device to the substrate before the heat dissipation structure is attached to the substrate, wherein the adhesive structure is between the surface-mounted device and the chip-containing structure.

16. A package structure, comprising:
a substrate;
a heat dissipation structure over the substrate;
a chip-containing structure between the substrate and the heat dissipation structure;
an adhesive structure between the heat dissipation structure and the substrate, wherein the heat dissipation structure, the substrate, and the adhesive structure together surround a first space containing the chip-containing structure; and
a through-hole in the adhesive structure, wherein the through-hole connects the first space to a second space outside of the first space.

17. The package structure as claimed in claim 16, further comprising:
a surface-mounted device bonded to the substrate, wherein the adhesive structure is between the surface-mounted device and the chip-containing structure.

18. The package structure as claimed in claim 16, wherein the adhesive structure comprises:
a first adhesive ring laterally and continuously surrounding a lower portion of the chip-containing structure; and
a second adhesive element on the first adhesive ring, wherein the second adhesive element laterally surrounds an upper portion of the chip-containing structure, and the through-hole is in a sidewall or a corner of the second adhesive element.

19. The package structure as claimed in claim 18, further comprising:
a second through-hole in a second sidewall or a second corner of the second adhesive element.

20. The package structure as claimed in claim 16, wherein the adhesive structure comprises:
a first adhesive element laterally surrounding a lower portion of the chip-containing structure;
a second adhesive element on the first adhesive ring, wherein the second adhesive element laterally surrounds an upper portion of the chip-containing structure, and the through-hole is in a sidewall or a corner of the second adhesive element; and
a second through-hole is in the first adhesive element.
